(19) United States
(12) Patent Application Publication
(10) Pub. No.: US 2026/0083011 A1
(43) Pub. Date: Mar. 19, 2026

(54) SEMICONDUCTOR DEVICE

(71) Applicant: Renesas Electronics Corporation, Tokyo (JP)

(72) Inventors: Koichi HASEGAWA, Tokyo (JP); Makoto TANAKA, Tokyo (JP)

(21) Appl. No.: 19/261,146

(22) Filed: Jul. 7, 2025

(30) Foreign Application Priority Data
Sep. 17, 2024 (JP) 2024-160197

(51) Int. Cl. H01L 25/065; H01L 23/00; H01L 23/495

(52) U.S. Cl. CPC H10W 90/00; H10W 70/417; H10W 72/50; H10W 72/5522; H10W 72/5524; H10W 72/871; H10W 72/884; H10W 72/886; H10W 72/926; H10W 72/932; H10W 72/936; H10W 90/20; H10W 90/28; H10W 90/284; H10W 90/732; H10W 90/736; H10W 90/752; H10W 90/756; H10W 90/766

(57) ABSTRACT

A reliability of a semiconductor device can be improved by measuring a value of a current flowing through a power transistor accurately. A semiconductor chip includes a power transistor and a source electrode electrically connected to a source region of the power transistor. The source electrode and a lead terminal are electrically connected to each other via a wire. The source electrode includes detection points for detecting the value of the current flowing through the power transistor. The detection points are arranged so as to sandwich a bonding point of the wire bonded to the source electrode.

### CROSS-REFERENCE TO RELATED APPLICATIONS

The disclosure of Japanese Patent Application No. 2024-160197 filed on Sep. 17, 2024, including the specification, drawings and abstract is incorporated herein by reference in its entirety.

### BACKGROUND

The present invention relates to a semiconductor device, particularly to a semiconductor device including a source electrode having a detection point for detecting a current flowing through a transistor.

A semiconductor device that seals a power semiconductor chip including a power transistor and a control semiconductor chip including a control circuit for controlling a gate potential of the power transistor is known. Also, the control semiconductor chip may have a function to detect the value of a load current of the power transistor. To detect the value of the load current, not only the power transistor, which is used as the main cell, but also a sense transistor for sensing a current is provided in the power semiconductor chip and also a detection point for detecting the value of the current is provided on a part of a source electrode of the power transistor. In a sense circuit provided in the control semiconductor chip, the value of the current flowing through the sense transistor is measured based on the value of the current flowing through the power transistor and a pre-set sense ratio.

There are disclosed techniques listed below.
[Patent Document 1] U.S. Patent Application Publication No. 2023/0369278
[Patent Document 2] Japanese Unexamined Patent Application Publication No. 2023-69756

For example, Patent Document 1 discloses a technique for stacking a control semiconductor chip on a power semiconductor chip and also discloses a semiconductor device in which these semiconductor chips are sealed. Furthermore, a source electrode of the power semiconductor chip in Patent Document 1 is electrically connected to a lead terminal via a wire.

Patent Document 2 discloses a technique for arranging a power semiconductor chip and a control semiconductor chip in a flat manner and also discloses a semiconductor device in which these semiconductor chips are sealed. The control semiconductor chip in Patent Document 2 has a sense circuit. Also, a source electrode of the power semiconductor chip in Patent Document 2 is electrically connected to a lead terminal via a clip.

### SUMMARY

As described above, to detect the load current, the detection point for detecting the value of the current is provided on a part of the source electrode of the power transistor. However, when the source electrode is electrically connected to the lead terminal via a wire, assembly variations such as a misalignment of a bonding point of a wire or a variability of a bonding area may occur.

The detection point is arranged to obtain a representative value (average value) of the potential of the power transistor. However, as the distance from the bonding point of the wire and the source electrode increases, a voltage drop occurs, and hence, it causes a gradient in a surface potential distribution of the source electrode. Therefore, it becomes difficult to stably obtain the same potential from the detection point for each semiconductor device due to the influence of the assembly variations, and hence, it causes that it is difficult to measure the value of the current flowing through the power transistor accurately. Consequently, there is a problem that the reliability of the semiconductor device is reduced.

Other problems and novel features will become apparent from the description and accompanying drawings of this specification.

The typical ones of the embodiments disclosed in the present application will be briefly described as follows.

A semiconductor device according to one embodiment includes a die pad, a first semiconductor chip mounted on the die pad, and a first lead terminal spaced apart from the die pad. The first semiconductor chip has a power transistor, and a first source electrode electrically connected to the source region of the power transistor. The first source electrode is electrically connected to the first lead terminal via a first bonding member made of conductive material. The first source electrode includes a first detection point and a second detection point each for detecting a value of a current flowing through the power transistor. The first detection point and the second detection point are arranged so as to sandwich a first bonding point of the first bonding member bonded to the first source electrode.

According to one embodiment, the reliability of the semiconductor device can be improved.

### BRIEF DESCRIPTION OF THE DRAWINGS

FIG. 1 is an equivalent circuit diagram showing a semiconductor device according to a first embodiment.

FIG. 2 is a plan view showing a mounting configuration of the semiconductor device according to the first embodiment.

FIG. 3A is a cross-sectional view along a line A-A shown in FIG. 2.

FIG. 3B is a cross-sectional view along a line B-B shown in FIG. 2.

FIG. 4 is an enlarged plan view at a portion of FIG. 2.

FIG. 5 is an enlarged plan view at a portion of FIG. 2.

FIG. 6 is a plan view for explaining a position of a detection point in the first embodiment.

FIG. 7 is a cross-sectional view showing a power transistor and a sense transistor in the first embodiment.

FIG. 8 is a cross-sectional view showing a MOSFET in the first embodiment.

FIG. 9 is an enlarged plan view at a main portion, showing a semiconductor device in an examined example.

FIG. 10 is an experimental data obtained by the present inventors of the present application.

FIG. 11A is a cross-sectional view along the line A-A shown in FIG. 2, showing a manufacturing process of the semiconductor device according to the first embodiment.

FIG. 11B is a cross-sectional view along the line B-B shown in FIG. 2, showing the manufacturing process of the semiconductor device according to the first embodiment.

FIG. 12A is a cross-sectional view along the line A-A shown in FIG. 2, showing a manufacturing process of the semiconductor device following FIG. 11.

FIG. 12B is a cross-sectional view along line B-B shown in FIG. 2, showing the manufacturing process of the semiconductor device following FIG. 11.

### DETAILED DESCRIPTION

Hereinafter, embodiments are described in detail with reference to the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In the present application, the X direction, Y direction, and Z direction described intersect and are orthogonal to each other. In the present application, the Z direction is described as the vertical direction, depth direction, or thickness direction of a structure. Also, expressions such as “plan view” or “plan view” used in the present application mean viewing the plane constituted by the X direction and Y direction from the Z direction.

### First Embodiment

### <Equivalent Circuit of Semiconductor Device>

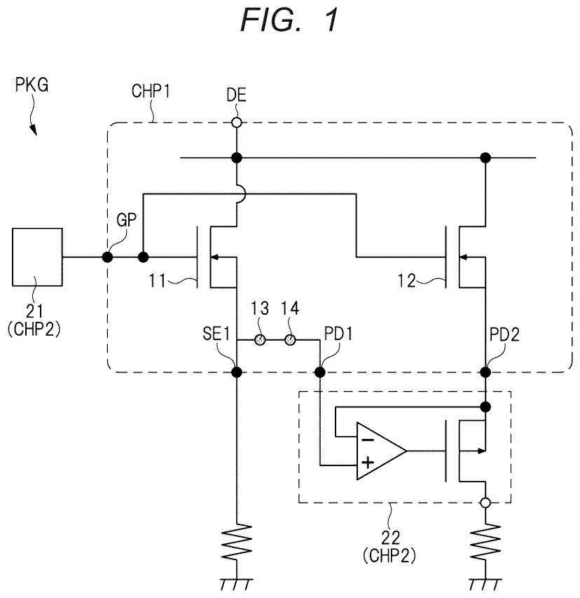

The semiconductor device PKG according to the first embodiment will be described below with reference to FIG. 1. The semiconductor device PKG is a semiconductor package including a semiconductor chip CHP1 and a semiconductor chip CHP2.

As shown in FIG. 1, the semiconductor chip CHP1 has a power transistor 11 and a sense transistor 12. The power transistor 11 composes the main cell of the semiconductor chip CHP1. The sense transistor 12 is used when detecting the value of the current flowing through the power transistor 11.

For example, the power transistor 11 and the sense transistor 12 configures a current mirror circuit such that “Value of Current flowing through Power transistor 11:Value of Current flowing through Sense transistor 12=10000:1 (sense ratio)”.

Furthermore, the source electrode SE1 of the power transistor 11 includes a detection point 13 and a detection point 14 each for detecting the value of the current flowing through the power transistor 11. The main feature of the first embodiment is that not only the detection point 13 but also the detection point 14 is provided, which will be described in detail later.

The semiconductor chip CHP2 has a gate potential control circuit 21 and a sense circuit 22. The gate potential control circuit 21 is electrically coupled to the gate electrode of each of the power transistor 11 and the sense transistor 12. The gate potential control circuit 21 controls the gate potential supplied to the power transistor 11 and controls on/off of the power transistor 11.

The sense circuit 22 is electrically coupled to each of the source electrode SE1 of the power transistor 11 via the detection point 13 and the detection point 14 and the source region of the sense transistor 12. The sense circuit 22 measures the value of the current flowing through the power transistor 11 based on the value of the current flowing through the sense transistor 12 and a pre-set sense ratio.

For more details, the sense circuit 22 receives the source voltage of the sense transistor 12 from the pad PD2 electrically coupled to the source region of the sense transistor 12, and the power transistor 11 receives the source voltage of the power transistor 11 from the pad PD1 electrically coupled to the source region of the power transistor 11. Also, the sense circuit 22 corrects such that the difference between the source voltage of the sense transistor 12 and the source voltage of the power transistor 11 is to be zero. In other words, the sense circuit 22 corrects such that the source voltage of the sense transistor 12 and the source voltage of the power transistor 11 are to be equal to each other. Subsequently, the sense circuit 22 converts the sense current, which is input from the pad PD2, into a voltage signal. In this way, the value of the current flowing through the power transistor 11 is measured based on the voltage signal and the pre-set sense ratio.

The sense ratio is “Value of Current flowing through Power transistor 11/Value of Current flowing through Sense transistor 12”. The “Value of Current flowing through Sense transistor 12” can be calculated by replacing it with “Source voltage of Power transistor 11 input from Pad PD1/Value of Resistance of Sense transistor 12”.

If an abnormal value such as an overcurrent is detected as the value of the current flowing through the power transistor 11, the gate potential control circuit 21 controls the gate potential supplied to the power transistor 11 (for example, controls to turn off the power transistor 11).

### <Mounting Configuration of Semiconductor Device>

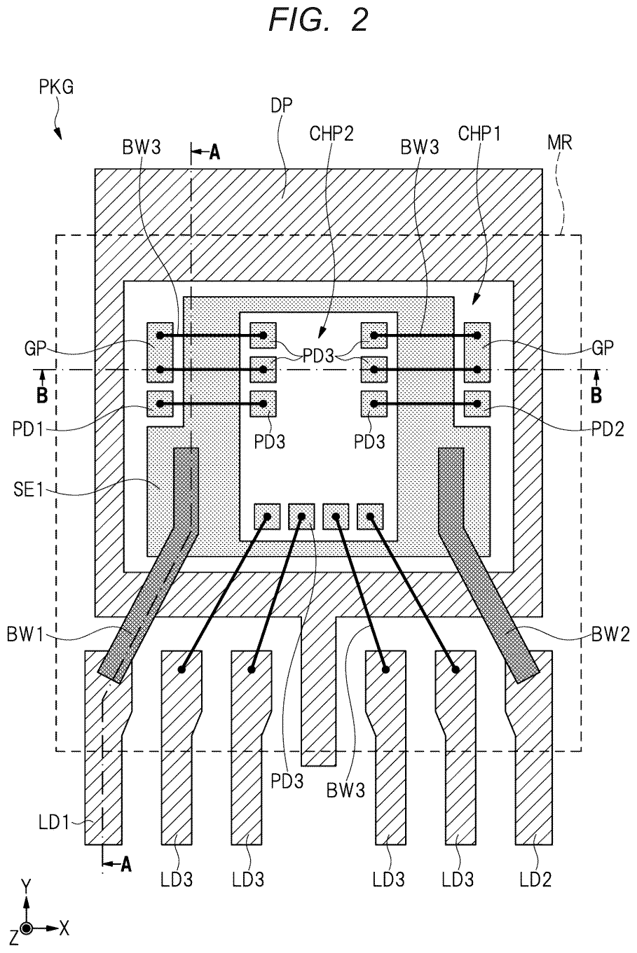

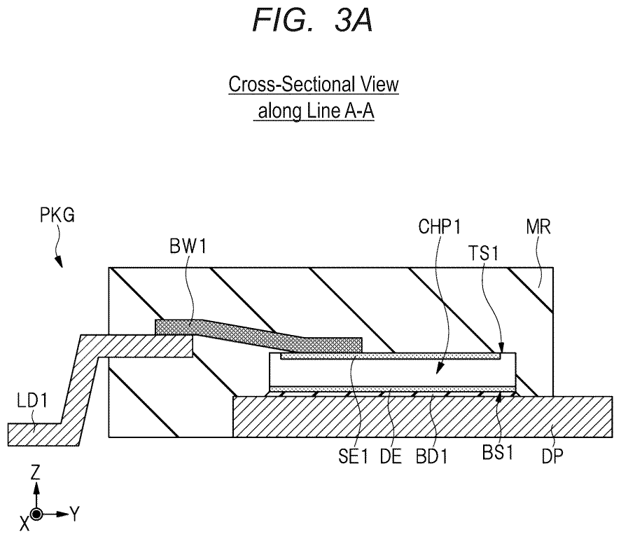

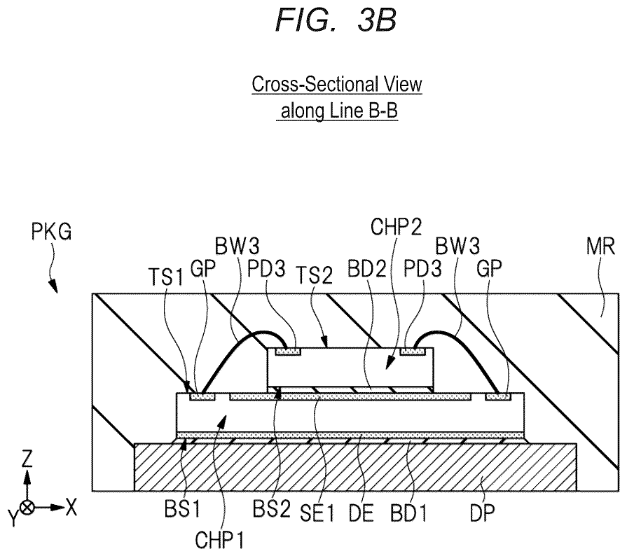

The mounting configuration of the semiconductor device PKG will be described below with reference to FIGS. 2 and 3. FIG. 3A shows a cross-sectional view along line A-A shown in FIG. 2. FIG. 3B shows a cross-sectional view along line B-B shown in FIG. 2.

As shown in FIGS. 2 and 3, the semiconductor device PKG includes a semiconductor chip CHP1 and a semiconductor chip CHP2, a die pad DP, a lead terminal LD1, a lead terminal LD2, a plurality of lead terminals LD3, a wire BW1, a wire BW2, a plurality of wires BW3, and a sealing resin MR.

The die pad DP, the lead terminal LD1, the lead terminal LD2 and the plurality of lead terminals LD3 are arranged so as to be spaced apart from each other and are made of a metal material such as copper alloy.

The semiconductor chip CHP1 has an upper surface TS1 and a lower surface BS1. The semiconductor chip CHP1 has a source electrode SE1, a gate pad GP, a pad PD1 and a pad PD2 each formed on the upper surface TS1. The source electrode SE1 and the pad PD1 are electrically connected to the source region of the power transistor 11. The gate pad GP is electrically connected to the gate electrode of each of the power transistor 11 and the sense transistor 12. The pad PD2 is electrically connected to the source region of the sense transistor 12.

Also, the semiconductor chip CHP1 has a drain electrode DE formed on the lower surface BS1. The drain electrode DE is electrically connected to the drain region of each of the power transistor 11 and the sense transistor 12.

The semiconductor chip CHP1 is mounted on the die pad DP via a conductive bonding material BD1 such that the lower surface BS1 facing the die pad DP. That is, the drain electrode DE is electrically connected to the die pad DP via the conductive bonding material BD1. The conductive bonding material BD1 is, for example, a silver paste.

The semiconductor chip CHP2 has an upper surface TS2 and a lower surface BS2. The semiconductor chip CHP2 has a plurality of pads PD3 formed on the upper surface TS2. The semiconductor chip CHP2 is mounted on the source electrode SE1 via an insulative bonding material BD2 such that the lower surface BS2 facing the upper surface TS1 of the semiconductor chip CHP1. The insulative bonding material BD2 is, for example, a Die Attach Film (DAF) material.

The source electrode SE1 is electrically connected to the lead terminal LD1 via the wire BW1, which is a bonding member made of conductive material. The source electrode SE1 is also electrically connected to the lead terminal LD2 via the wire BW2, which is a bonding member made of conductive material. As shown in FIG. 2, the semiconductor chip CHP2 is located between the wire BW1 and the wire BW2. The gate pad GP, the pad PD1 and the pad PD2 are electrically connected to parts of the plurality of pads PD3 via a wire BW3, which is a bonding member made of conductive material, respectively. Other parts of the plurality of pads PD3 are electrically connected to the plurality of lead terminals LD3 via the wire BW3, respectively.

To reduce the resistance component on the source electrode SE1, a wire having a larger thickness than a wire used as the wire BW3 is used as each of the wire BW1 and the wire BW2. That is, the diameter of each of the wire BW1 and the wire BW2 is larger than the diameter of each wire BW3. The wire BW1 and the wire BW2 are made of, for example, aluminum or aluminum alloy, while the wire BW3 is made of gold.

The semiconductor chip CHP1 and the semiconductor chip CHP2, the die pad DP, the lead terminal LD1, the lead terminal LD2, the plurality of lead terminals LD3, the wire BW1, the wire BW2 and the plurality of wires BW3 are sealed with the sealing resin MR. A part of each of the die pad DP, the lead terminal LD1, the lead terminal LD2 and the plurality of lead terminals LD3 is exposed from the sealing resin MR. The sealing resin MR is made of thermosetting resin material such as an epoxy resin.

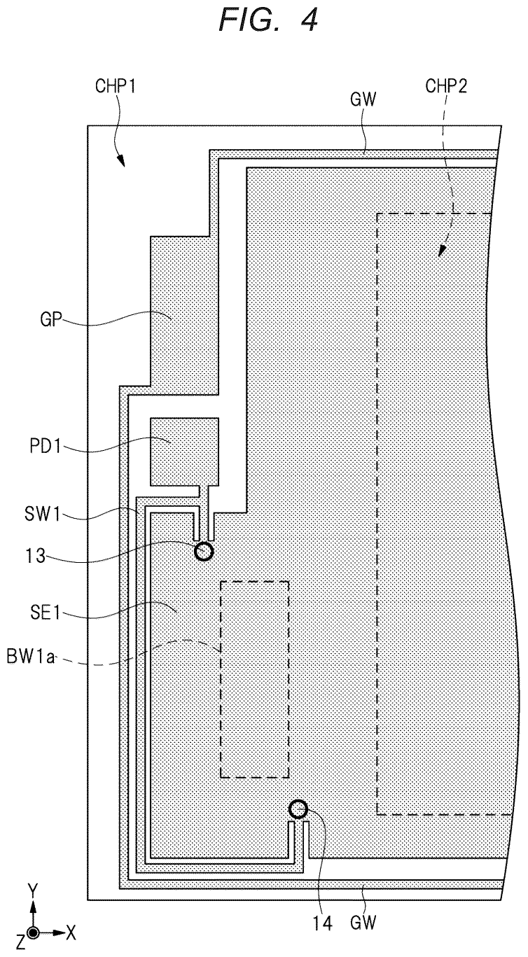

Below, the detailed structure around detection points 13 and 14 will be described using FIG. 4. Note that the bonding point BW1a shown in FIG. 4 is where the wire BW1 is bonded to the source electrode SE1.

As shown in FIG. 4, the source electrode SE1 includes the detection point 13 and the detection point 14 each for detecting the value of the current flowing through the power transistor 11, which are located near the bonding point BW1a. The detection point 13 and the detection point 14 are arranged so as to sandwich the bonding point BW1a of the bonding member, which is bonded to the source electrode SE1, therebetween.

The source wiring SW1 drawn from each of the detection point 13 and the detection point 14 is routed around the source electrode SE1, and is electrically connected to the pad PD1. To secure the area for placing the source wiring SW1, a part of the source electrode SE1 is processed. In other words, the part of the source electrode SE1 where the source wiring SW1 is connected is the detection points 13 and 14. Here, for convenience, separate codes are assigned, but the source electrode SE1, the source wiring SW1 and the pad PD1 are made of the same conductive film and are formed in a body.

The source electrode SE1 is electrically connected to the sense circuit 22 of the semiconductor chip CHP2 via the detection point 13, the detection point 14, the source wiring SW1, the pad PD1, the wire BW3 and the pad PD3.

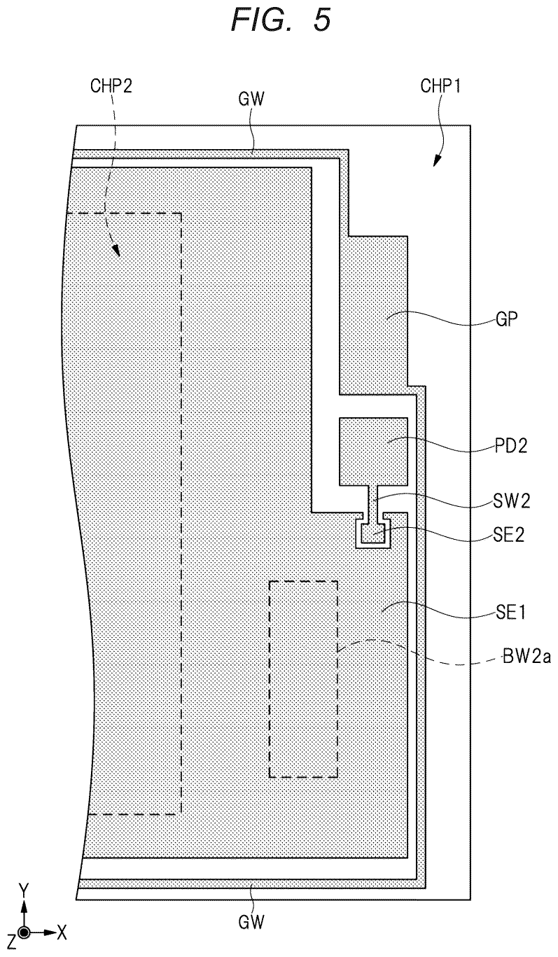

Below, the detailed structure around the sense transistor 12 will be described using FIG. 5. Note that the bonding point BW2a shown in FIG. 5 is where the wire BW2 is bonded to the source electrode SE1.

As shown in FIG. 5, the semiconductor chip CHP1 has a source electrode SE2 formed on the upper surface TS1. The source electrode SE2 is spaced away from the source electrode SE1. The power transistor 11 is formed below the source electrode SE1. The sense transistor 12 is formed below the source electrode SE2. The source region of the sense transistor 12 is electrically connected to the source electrode SE2.

The source wiring SW2 drawn from the source electrode SE2 is electrically connected to the pad PD2. Note that the source electrode SE2, the source wiring SW2 and the pad PD2 are made of the same conductive film and are formed in a body.

The source region of the sense transistor 12 is electrically connected to the sense circuit 22 of the semiconductor chip CHP2 via the source electrode SE2, the source wiring SW2, the pad PD2, the wire BW3 and the pad PD3.

Also, as shown in FIGS. 4 and 5, the gate wiring GW drawn from the gate pad GP is routed around the source electrode SE1. Although not shown, the gate wiring GW is electrically connected to the gate electrode of each of the power transistor 11 and the sense transistor 12. Note that the gate pad GP and gate wiring GW are made of the same conductive film and are formed in a body.

The gate electrode of each of the power transistor 11 and the sense transistor 12 is electrically connected to the gate potential control circuit 21 of the semiconductor chip CHP2 via the gate wiring GW, the gate pad GP, the wire BW3 and the pad PD3.

Also, the semiconductor chip CHP2 is mounted on the source electrode SE1 so as to be located between the bonding point BW1a and the bonding point BW2a.

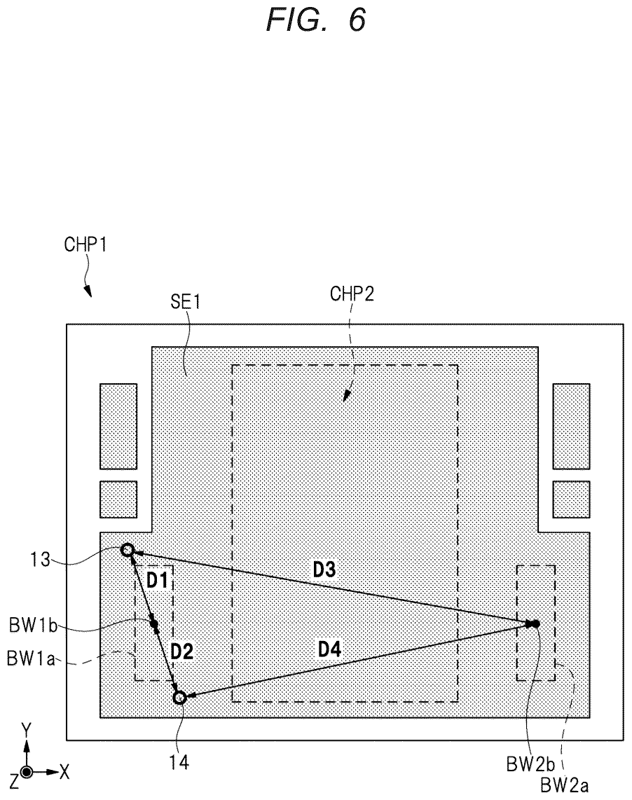

Below, the position of each of the detection point 13 and the detection point 14 will be described by using FIG. 6.

As shown in FIG. 6, a distance D1 is the distance from the detection point 13 to the center BW1b of the bonding point BW1a. A distance D2 is the distance from the detection point 14 to the center BW1b of the bonding point BW1a. A distance D3 is the distance from the detection point 13 to the center BW2b of the bonding point BW2a. A distance D4 is the distance from the detection point 14 to the center BW2b of the bonding point BW2a. The distances D1 and D2 are less than the distances D3 and D4, respectively, and are, for example, 0.5 mm or more and 1.1 mm or less.

During designing, the distances D1 and D2 are the same. However, the distance D1 and the distance D2 may differ from each other in such a case that the assembly variations occurred.

### <Cross-Sectional Structure of Power Transistor and Sense Transistor>

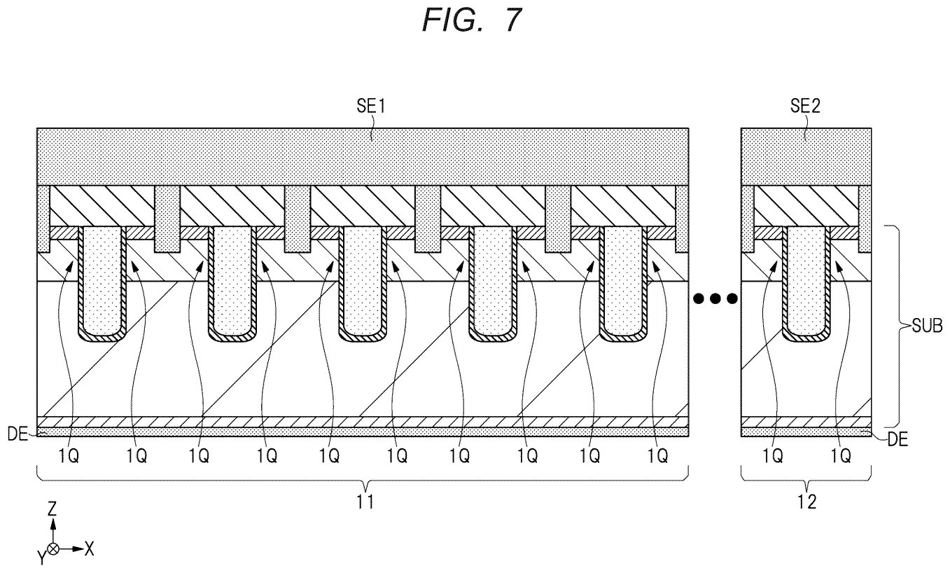

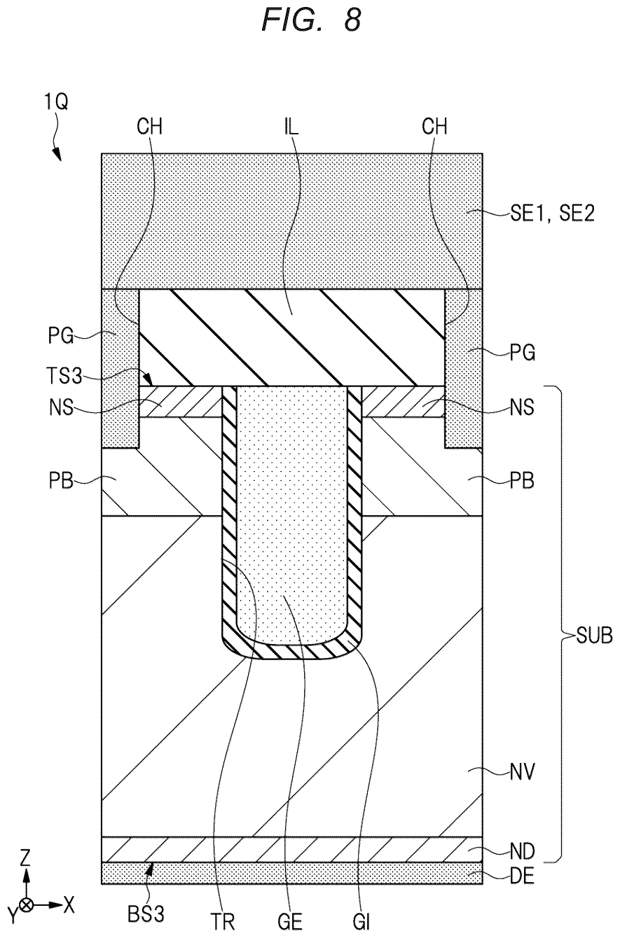

Below, the cross-sectional structure of a MOSFET (Metal Oxide Semiconductor Field Effect Transistor) composing each of the power transistor 11 and the sense transistor 12 will be described by using FIGS. 7 and 8.

As shown in FIG. 7, a plurality of MOSFETs 1Q, whose conductive type is n-type, is formed on the semiconductor substrate SUB. The power transistor 11 shown in FIG. 1 is composed of the plurality of MOSFETs 1Q coupled in parallel. The sense transistor 12 shown in FIG. 1 is composed of at least one MOSFET 1Q. The sense transistor 12 may also be composed of the plurality of MOSFETs 1Q coupled in parallel, but in that case, the number of the MOSFETs 1Q composing the sense transistor 12 is less than the number of the MOSFETs 1Q composing the power transistor 11.

The sense ratio is substantially determined by the ratio of the area where the MOSFETs 1Q composing the power transistor 11 are formed to the area where the MOSFETs 1Q composing the sense transistor 12 are formed.

Below, the detailed structure of the MOSFET 1Q will be described using FIG. 8.

As shown in FIG. 8, the semiconductor substrate SUB has an upper surface TS3 and a lower surface BS3 and is made of n-typed silicon. The semiconductor substrate SUB includes a drift region NV whose conductive type is n-type and a drain region ND whose conductive type is n-type. The drain region ND is formed in the semiconductor substrate SUB so as to have a predetermined thickness from the lower surface BS3 toward the upper surface TS3 of the semiconductor substrate SUB. The drain region ND has a higher impurity concentration than the drift region NV.

The semiconductor substrate SUB may be an n-typed mono-crystal silicon substrate, or it may be a laminate of an n-typed silicon substrate and an n-typed semiconductor layer grown by introducing phosphorus (P) through an epitaxial growth method on the n-typed silicon substrate.

A drain electrode DE is formed on the lower surface BS3 of the semiconductor substrate SUB. The drain electrode DE is comprised of a metal film, such as an aluminum film, titanium film, nickel film, gold film or silver film, of a single layer, or a laminated film formed by appropriately laminating these metal films. The drain region ND and the drain electrode DE are formed across the entire lower surface BS3 of the semiconductor substrate SUB. The drain potential is supplied from the drain electrode DE to the semiconductor substrate SUB (drain region ND, drift region NV).

A trench TR is formed in the semiconductor substrate SUB, reaching a predetermined depth from the upper surface TS3 of the semiconductor substrate SUB. Inside the trench TR, a gate electrode GE is formed via a gate insulating film GI. The gate insulation film GI is made of, for example, a silicon oxide film. The gate electrode GE is made of, for example, a polycrystalline silicon film into which n-type impurities are introduced.

A p-type body region PB is formed in the semiconductor substrate SUB, reaching a predetermined depth from the upper surface TS3 of the semiconductor substrate SUB. The depth of the body region PB from the upper surface TS3 of the semiconductor substrate SUB is shallower than the depth of the trench TR from the upper surface TS3 of the semiconductor substrate SUB. An n-type source region NS is formed within the body region PB. The source region NS has a higher impurity concentration than the drift region NV. The portion of the body region PB adjacent to the gate electrode GE via the gate insulating film GI and located between the source region NS and the drift region NV forms the channel region of the MOSFET1Q.

An interlayer insulating film IL is formed on the upper surface TS3 of the semiconductor substrate SUB, covering the trench TR. The interlayer insulating film IL is made of, for example, a silicon oxide film.

A hole CH is formed in the interlayer insulating film IL. The hole CH penetrates the interlayer insulating film IL and the source region NS and reaches the body region PB. Although not shown here, a hole CH reaching the gate electrode GE is also formed in the interlayer insulating film IL. A plug PG is embedded inside the hole CH. The plug PG consists of, for example, a first barrier metal film and a first conductive film formed on the first barrier metal film. The first barrier metal film is made of, for example, a laminated film of a titanium film and a titanium nitride film. The first conductive film is, for example, a tungsten film.

A source electrode SE1 is formed on the interlayer insulating film IL. The source electrode SE1 is electrically connected to the source region NS and the body region PB via the plug PG, supplying a source potential to these impurity regions. Note that a source electrode SE2 is formed above the MOSFET1Q constituting the sense transistor 12.

Although not shown here, the gate pad GP, the gate wiring GW, the pad PD1, the source wiring SW1, the pad PD2, and the source wiring SW2, as shown in FIG. 4 and FIG. 5, are also formed on the interlayer insulating film IL. The gate pad GP is electrically connected to the gate electrode GE via the gate wiring GW and the plug PG, supplying a gate potential to the gate electrode GE.

The source electrode SE1, source electrode SE2, gate pad GP, gate wiring GW, pad PD1, source wiring SW1, pad PD2, and source wiring SW2 consist of, for example, a second barrier metal film and a second conductive film formed on the second barrier metal film. The second barrier metal film is, for example, a titanium tungsten film. The second conductive film is, for example, an aluminum alloy film with added copper or silicon.

### <Arrangement of Detection Points 13 and 14>

As described above, the detection points (detection point 13, detection point 14) are arranged to obtain a representative value (average value) of the potential of power transistor 11. However, as the distance from the bonding point BW1a increases, a voltage drop occurs, causing a gradient in the surface potential distribution of the source electrode SE1. Therefore, when assembly variations occur, it becomes difficult to stably obtain the same potential from the detection points for each semiconductor device PKG. In other words, variations occur in the source voltage of the power transistor 11 input from the pad PD1, resulting in variations in the sense ratio. Consequently, it becomes difficult to accurately measure the value of the current flowing through the power transistor 11.

For example, as a bonding member for bonding the source electrode SE1 and the lead terminal LD1, a large-area clip as shown in Patent Document 2 may be considered. Since the clip can be configured with a wider width than the wire BW1, it can be bonded to most of the source electrode SE1. As a result, it is easier to select a location where the gradient of the surface potential distribution is almost nonexistent as the detection point. However, when mounting a semiconductor chip CHP2 on the source electrode SE1 as in the first embodiment, the bonding area of the bonding member becomes limited. Therefore, in the first embodiment, a wire BW1 with a narrower width than the clip is used.

On the other hand, as a market demand for the semiconductor device PKG including the power transistor 11, a reduction of on-resistance is required. Therefore, by optimizing the channel region and the drift region NV of the MOSFET1Q, the on-resistance of the power transistor 11 is reduced by lowering the resistance of the MOSFET1Q.

However, by lowering the resistance of the MOSFET1Q, the resistance component of the source electrode SE1 becomes relatively more influential as the distance from the bonding point BW1a increases. As a result, even if the chip size is the same and the bonding state of the wire BW1 is the same, the gradient of the surface potential distribution of the source electrode SE1 becomes larger. Therefore, for example, if the position of the bonding point BW1a of the wire BW1 shifts, the variation in the source voltage of the power transistor 11 input from the pad PD1 also becomes larger. In other words, by lowering the resistance of the MOSFET1Q, the variation in the sense ratio is greatly affected by assembly variations.

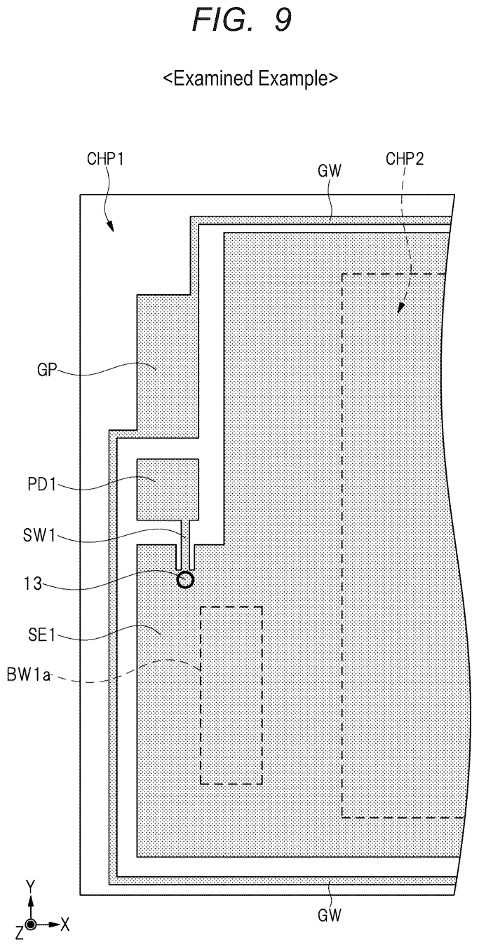

FIG. 9 shows a semiconductor device of an examined example studied by the inventors of the present application. As can be seen by comparing FIG. 9 and FIG. 4, in the examined example, only the detection point 13 is provided, and the detection point 14 is not provided.

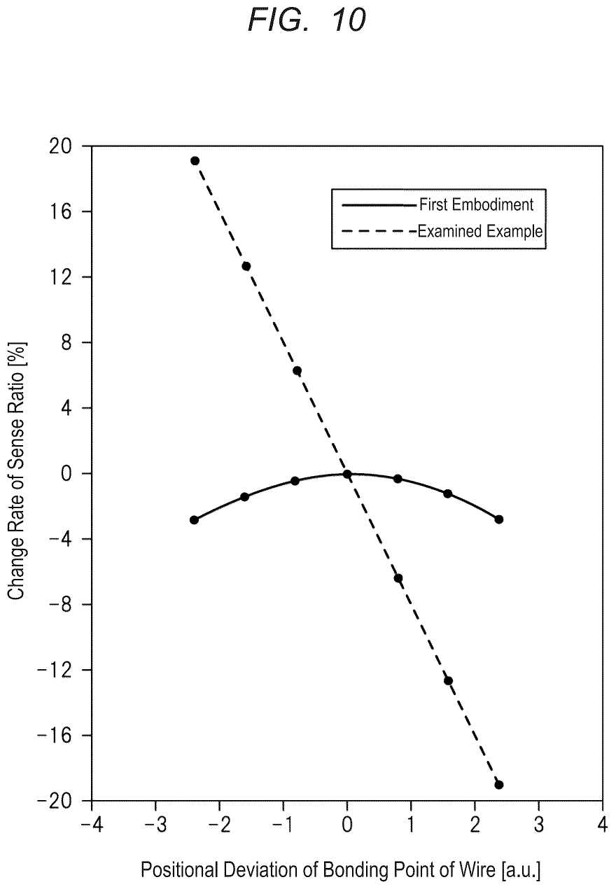

FIG. 10 shows the relationship between the magnitude of the misalignment of the bonding point BW1a of the wire BW1 and the change rate of the sense ratio. As shown in FIG. 10, in the examined example, as the misalignment of the bonding point BW1a gets larger, the change rate of the sense ratio gets higher, and hence, it causes that it is difficult to measure the value of the current flowing through the power transistor 11 accurately.

In contrast, in the first embodiment, the detection points 13 and 14 are provided so as to sandwich the bonding point BW1a therebetween. As explained in FIG. 6, during design, the distances D1 and D2 are the same. However, when assembly variations occur, the distances D1 and D2 differ. For example, if the position of the bonding point BW1a shifts in the Y direction (upward in FIG. 6), the distance D2 becomes longer, but correspondingly, the distance D1 becomes shorter. Therefore, as shown in FIG. 10, by averaging the voltages detected at the two points of detection points 13 and 14, the variation in the change rate of the sense ratio can be suppressed.

Thus, in the first embodiment, even if assembly variations occur while reducing the on-resistance of the power transistor 11, it is possible to stably obtain almost the same potential from detection points 13 and 14 for each semiconductor device PKG. Therefore, it becomes easier to accurately measure the value of the current flowing through the power transistor 11, and the reliability of the semiconductor device PKG can be improved.

Note that two detection points like detection points 13 and 14 may be provided around the bonding point BW2a so as to sandwich the bonding point BW2a therebetween. Also, the number of the detection points is not limited to two and may be three or more.

However, when providing detection points, as with the source wiring SW1, lead-out wiring is required to draw out from the detection points, but MOSFET1Q cannot be formed below the lead-out wiring. In other words, increasing the number of detection points reduces the area where MOSFET1Q can be formed. As a result, the on-resistance of the power transistor 11 increases. Therefore, it is more preferable that only the necessary number of detection points are provided.

In the first embodiment, in order to measure the value of the current flowing through the power transistor 11 accurately and also to suppress the increasement of the on-resistance of the power transistor 11, two detection points (detection point 13, detection point 14) are provided around the bonding point BW1a, and no detection points are provided around the bonding point BW2a.

### <Method of Manufacturing Semiconductor Device>

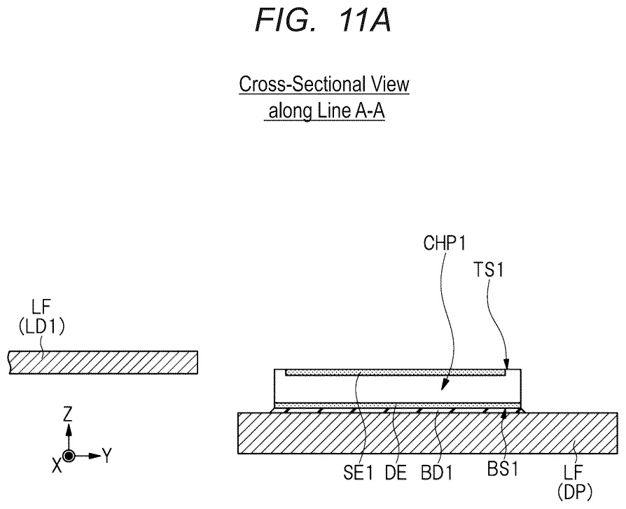

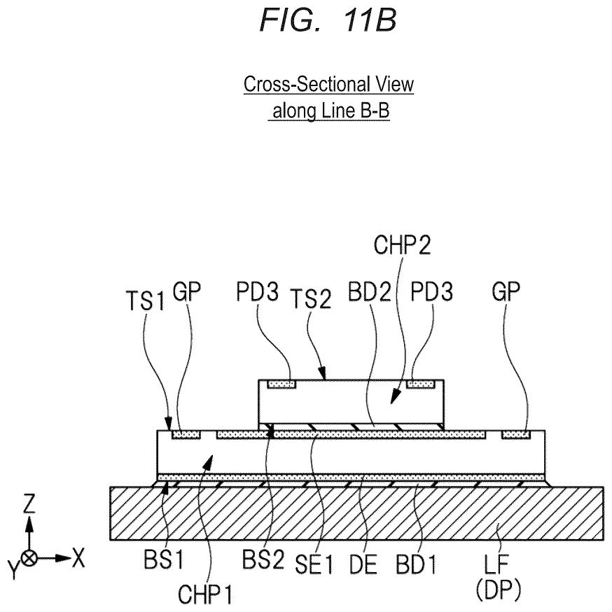

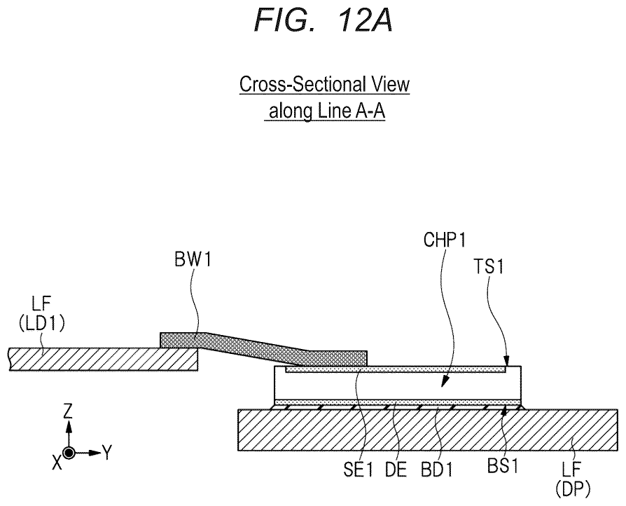

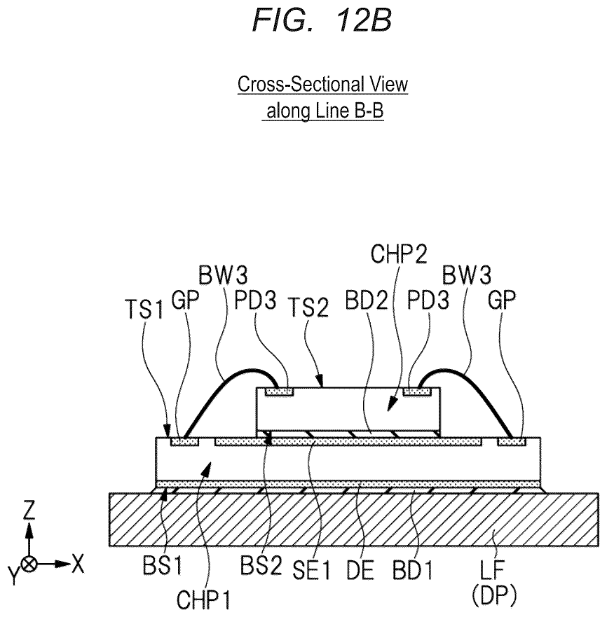

The manufacturing process included in the manufacturing method of the semiconductor device PKG will be described below using FIG. 11A, FIG. 11B, FIG. 12A, and FIG. 12B.

As shown in FIG. 11A and FIG. 11B, first, prepare the semiconductor chip CHP1, the semiconductor chip CHP2, and the lead frame LF. The lead frame LF includes lead terminals LD1, LD2, LD3, and die pad DP.

Next, mount the semiconductor chip CHP1 on the die pad DP via the conductive bonding material BD1, so that the lower surface BS1 of the semiconductor chip CHP1 faces the die pad DP. Then, mount the semiconductor chip CHP2 on the source electrode SE1 via the insulative bonding material BD2, so that the lower surface BS2 of the semiconductor chip CHP2 faces the upper surface TS1 of the semiconductor chip CHP1.

Next, as shown in FIGS. 12A and 12B, wire bonding is performed. The wire BW1 electrically connects the source electrode SE1 and the lead terminal LD1. The wire BW3 electrically connects the pad PD3, which is electrically connected to gate potential control circuit 21, and the gate pad GP. Although not shown here, the wire BW2 electrically connects the source electrode SE1 and the lead terminal LD2. The wire BW3 electrically connects the pad PD3, which is electrically connected to gate potential control circuit 21, and the pad PD1. The wire BW3 electrically connects the pad PD3, which is electrically connected to sense circuit 22, and the pad PD2. Multiple wires BW3 electrically connect other multiple pads PD3 and multiple lead terminals LD3.

Subsequently, the following manufacturing processes are performed to produce the semiconductor device PKG shown in FIGS. 2, 3A, and 3B. First, the semiconductor chip CHP1, semiconductor chip CHP2, die pad DP, lead terminal LD1, lead terminal LD2, multiple lead terminals LD3, wire BW1, wire BW2, and multiple wires BW3 are sealed with an encapsulating resin MR. Note that parts of the die pad DP, lead terminal LD1, lead terminal LD2, and multiple lead terminals LD3 are exposed outside the encapsulating resin MR.

Next, the die pad DP, lead terminal LD1, lead terminal LD2, and lead terminal LD3 are cut out from the lead frame LF. Then, the lead terminal LD1, lead terminal LD2, and lead terminal LD3 are bent. Thus, the semiconductor device PKG can be manufactured.

The present invention has been specifically described based on the above embodiment, but it is not limited to the above embodiment and can be variously modified without departing from the gist thereof.

For example, in the above embodiment, the use of a wire as a bonding member made of conductive material for bonding to the lead terminal was described. However, if the width (area) of the portion bonded to the source electrode SE1 or the pad PD3 is small, a clip may be used as the bonding member for bonding to the lead terminal.

What is claimed is:

1. A semiconductor device comprising:
a die pad;
a first semiconductor chip mounted on the die pad; and
a first lead terminal spaced apart from the die pad,
wherein the first semiconductor chip has:
a power transistor; and
a first source electrode electrically connected to a source region of the power transistor,
wherein the first source electrode is electrically connected to the first lead terminal via a first bonding member, the first bonding member being made of conductive material,
wherein the first source electrode includes a first detection point and a second detection point each for detecting a value of a current flowing through the power transistor, and
wherein the first detection point and the second detection point are arranged so as to sandwich a first bonding point of the first bonding member bonded to the first source electrode.

2. The semiconductor device according to claim 1, further comprising:
a second semiconductor chip; and
a second lead terminal spaced apart from the die pad and the first lead terminal,
wherein the first source electrode is electrically connected to the second lead terminal via a second bonding member, the second bonding member being made of conductive material, and
wherein, in plan view, the second semiconductor chip is mounted on the first source electrode so as to be located between a second bonding point of the second bonding member bonded to the first source electrode and the first bonding point.

3. The semiconductor device according to claim 2, wherein no detection points for detecting the value of the current flowing through the power transistor are provided around the second bonding point.

4. The semiconductor device according to claim 2, wherein a distance from the first detection point to a center of the first bonding point, or a distance from the second detection point to the center of the first bonding point, is less than a distance from the first detection point to a center of the second bonding point, or a distance from the second detection point to the center of the second bonding point.

5. The semiconductor device according to claim 2, wherein a distance from the first detection point to a center of the first bonding point, or a distance from the second detection point to the center of the first bonding point, is 0.5 mm or more, and is 1.1 mm or less.

6. The semiconductor device according to claim 2, wherein the first semiconductor chip further includes:
a first source wiring drawn from each of the first detection point and the second detection point; and
a first pad electrically connected to the first source wiring.

7. The semiconductor device according to claim 6,
wherein the first semiconductor chip further includes:
a sense transistor; and
a second pad electrically connected to a source region of the sense transistor,
wherein the second semiconductor chip includes:
a sense circuit for measuring the value of the current flowing through the power transistor based on a value of a current flowing through the sense transistor and a pre-set sense ratio;
a third pad electrically connected to the sense circuit; and
a fourth pad electrically connected to the sense circuit,
wherein the first pad is electrically connected to the third pad via a third bonding member, the third bonding member being made of conductive material, and
wherein the second pad is electrically connected to the fourth pad via a fourth bonding member, the fourth bonding member being made of conductive material.

8. The semiconductor device according to claim 7, wherein a diameter of each of the first bonding member and the second bonding member is larger than a diameter of each of the third bonding member and the fourth bonding member.

9. The semiconductor device, according to claim 7,
wherein each of the first bonding member and the second bonding member is a wire made of aluminum or an aluminum alloy, and
wherein each of the third bonding member and the fourth bonding member is a wire made of gold.
